(19) United States
(12) Patent Application Publication
(10) Pub. No.: US 2014/0360578 A1
(43) Pub. Date: Dec. 11, 2014

(54) SOLAR ENERGY SYSTEM INCLUDING A LIGHTGUIDE FILM

(71) Applicants: Anthony J. Nichol, Chicago, IL (US); Zane A. Coleman, Elmhurst, IL (US)

(72) Inventors: Anthony J. Nichol, Chicago, IL (US); Zane A. Coleman, Elmhurst, IL (US)

(21) Appl. No.: 14/117,577

(22) PCT Filed: May 10, 2012
(86) PCT No.: PCT/US12/37317

§ 371 Date: Nov. 13, 2013

Related U.S. Application Data
(60) Provisional application No. 61/485,933, filed on May 13, 2011.

(51) Int. Cl. G02B 6/42; F21S 11/00; F24J 2/06; G02B 6/10; H01L 31/052

(52) U.S. Cl. CPC G02B 6/4257; G02B 6/10; H01L 31/0522; F24J 2/06; F21S 11/002
USPC 136/259; 385/129; 385/31; 126/698; 359/591

(57) ABSTRACT

A solar energy system for collecting light includes at least one stretchable lightguide film configured to optically couple light into a lightguide condition in the at least one stretchable lightguide film. Also disclosed is a method for collecting light with a lightguide film that includes stretching or contracting the lightguide film having one or more coupling features to optically couple light into the lightguide film.

### CROSS REFERENCE TO RELATED APPLICATION

This application claims the benefit of U.S. Provisional Application No. 61/485,933, entitled “SOLAR ENERGY SYSTEM INCLUDING A LIGHTGUIDE FILM”, filed May 13, 2011, the entire contents of which are incorporated herein by reference.

### BACKGROUND

The subject matter disclosed herein relates generally to light collecting systems and, more particularly, to a solar energy system including a stretchable film-based lightguide suitable for optically coupling sunlight to a light collector.

Conventional solar energy systems are configured to track the sun as the light rays from the sun change orientation throughout the day and season. For directionally sensitive concentration systems, such as parabolic concentrators, this usually requires an expensive, sensitive and/or bulky solar tracking and actuation system to rotate the concentrator with the sun.

### BRIEF DESCRIPTION

In one aspect, a solar energy system for collecting light includes a stretchable lightguide film configured to optically couple light into a lightguide condition in the stretchable lightguide.

In another aspect, a solar energy system includes a stretchable lightguide film. One or more coupling features are positioned on or within the stretchable lightguide film. The one or more coupling features are configured to redirect incident light from a first angular range into a second angular range within the stretchable lightguide film to totally internally reflect the light in a lightguide condition. A tension adjustment mechanism is configured to stretch and contract the stretchable lightguide film such that the one or more coupling features redirect light incident from the first angular range into the second angular range.

In yet another aspect, a method for collecting light is provided. The method includes stretching or contracting a lightguide film including one or more coupling features to optically couple light into the lightguide.

### BRIEF DESCRIPTION OF THE DRAWINGS

FIG. 1 is a side view of an exemplary solar energy system including a stretchable lightguide film in a first configuration;

FIG. 2 is a side view of the solar energy system shown in FIG. 1 with the stretchable lightguide film in a second configuration different from the first configuration;

FIG. 3 is a top view of an exemplary lightguide film patterned with coupling features in a first configuration;

FIG. 4 is a top view of the lightguide film shown in FIG. 3 stretched from ne first configuration to a second configuration;

FIG. 5 is a side view of an exemplary solar energy system including a plurality of stretchable lightguide films forming a layered lightguide film;

FIG. 6 is a cross-sectional side view of an exemplary solar energy system. including a tension adjustment mechanism;

FIG. 7 is a cross-sectional side view of the exemplary solar energy system shown in FIG. 6 where the tension adjustment mechanism has stretched the lightguide film;

FIG. 8 is a cross-sectional side view of an exemplary solar energy system including a lower support plate and an upper protective plate;

FIG. 9 is a cross-sectional side view of an exemplary solar energy system that is vertically oriented and encapsulated;

FIG. 10 is a cross-sectional side view of an exemplary solar energy system that provides daylighting illumination; and

FIG. 11 is a cross-sectional side view of an exemplary solar energy system that provides solar thermal energy.

### DETAILED DESCRIPTION

The features and other details of several embodiments will now be more particularly described. It will be understood that particular embodiments described herein are shown by way of illustration and not as limitations. The features can be employed in various embodiments without departing from the scope of any particular embodiment. All parts and percentages are by weight unless otherwise specified. In the discussion, the terms above and below, up and down, upwardly and downwardly, and variants of these terms will be used to refer to the relative position of elements relative to the sun with the direction from the device toward the sun generally referred to herein as being in the up direction with the sun above the device. The terms above and below do not dictate that certain elements need to be above or below each other in the final use application. However, these terms may be convenient throughout the application to refer to the relative position of elements in the drawings.

### DEFINITIONS

“Optically coupled” as defined herein refers to coupling of two or more regions or layers such that the flux of light passing from one region to the other is not substantially reduced by Fresnel interfacial reflection losses due to differences in refractive indices between the regions. “Optical coupling” methods include methods of coupling wherein the two regions coupled together have similar refractive indices or using an optical adhesive with a refractive index substantially near or between the refractive index of the regions or layers. Examples of “optical coupling” include, without limitation, lamination using an index-matched optical adhesive, coating a region or layer onto another region or layer, or hot lamination using applied pressure to join two or more layers or regions that have substantially close refractive indices. Thermal transferring is another method that can be used to optically couple two regions of material. Forming, altering, printing, or applying a material on the surface of another material are other examples of optically coupling two materials. “Optically coupled” also includes forming, adding, or removing regions, features, or materials of a first refractive index within a volume of a material of a second refractive index such that light propagates from the first material to the second material. For example, a white light scattering ink (such as titanium dioxide in a methacrylate, vinyl, or polyurethane based binder) may be optically coupled to a surface of a polycarbonate or silicone film by inkjet printing the ink onto the surface. Similarly, a light scattering material such as titanium dioxide in a solvent applied to a surface may allow the light scattering material to penetrate or adhere in close physical contact with the surface of a polycarbonate or silicone film such that it is optically coupled to the film surface or volume.

“Lightguide” or “waveguide” refers to a region bounded by the condition that light rays propagating at an angle that is larger than the critical angle will reflect and remain within the region. In a lightguide, the light will reflect or TIR (totally internally reflect) if the angle (a) satisfies the condition α>sin⁻¹(n₂/n₁), where n₁ is the refractive index of the medium inside the lightguide and n₂ is the refractive index of the medium outside the lightguide. Typically, n₂ is air with a refractive index of n≈1, however, high and low refractive index materials can be used to achieve lightguide regions. The lightguide may include reflective components such as reflective films, aluminized coatings, surface relief features, and other components that can re-direct or reflect light. The lightguide may also contain non-scattering regions such as substrates. Light can be incident on a lightguide region from the sides or below and surface relief features or light scattering domains, phases or elements within the region can direct light into larger angles such that the light totally internally reflects, or into smaller angles such that the light escapes the lightguide. The lightguide does not need to be optically coupled to all of its components to be considered a lightguide. Light may enter from any face (or interfacial refractive index boundary) of the waveguide region and may totally internally reflect from the same or another refractive index interfacial boundary. A region can be functional as a waveguide or lightguide for purposes illustrated herein as long as the thickness is larger than the wavelength of light of interest.

“Film” refers to a thin layer or coating of material with a thickness substantially less than the length and width without regard to how the film is formed. For example, a film may be an extruded polymer, cast polymer, a thermoset polymer or thermoplastic polymer.

As used herein, the term “creep” refers to accumulated plastic deformation of a film, or a change in length of a film, that does not reverse or disappear when forces that act to stretch the film are removed.

The embodiments described herein relate generally to solar energy systems and, more particularly, to a solar energy system including a stretchable film-based lightguide configured to optically couple sunlight to a light collector. In one embodiment, a solar energy system includes a stretchable optical lightguide film defining a body configured to collect light. The light propagates within the body and through a plurality of lightguide strips optically coupled to the body. In a particular embodiment, an edge portion of the film is cut to form the plurality of lightguide strips continuous with the body. The strips are then bundled into one or more bundles and at the end of one or more bundles of strips, the light is optically coupled to one or more photovoltaic cells or another suitable light collector, such as, for example, a daylighting illumination fixture or a solar thermal device.

One or more light coupling features are operatively coupled to, such as formed on and/or at least partially within, the body of the stretchable optical lightguide film. The light coupling features are actuated and changed by stretching, contracting, or otherwise manipulating the lightguide film along one or more dimensions, for example along a length of the lightguide film. An advantage that may be realized in the practice of at least some embodiments of the described system and techniques is that the light at the body is coupled into the lightguide film to facilitate total internal reflection transfer within the lightguide film. In particular, as the light rays from the sun change orientation throughout the day and season, in one embodiment the lightguide film is stretched or contracted, as desired, to facilitate coupling of the light into the lightguide film. As a result, the solar energy system as described herein does not require an expensive, sensitive and/or bulky solar tracking and actuation system, as required by conventional directionally sensitive concentration systems, such as parabolic concentrators, to rotate the concentrator with the sun.

### Stretchable Optical Lightguide Film

In one embodiment, the stretchable optical lightguide film is a thin, flexible film including a light transmitting material. In one embodiment, the thickness of the film, lightguide or lightguide region is within a range of 0.005 millimeters (nun) to 0.5 mm or more specifically, within a range of 0.025 mm to 0.5 mm, or, even more specifically, within a range of 0.050 mm to 0.175 mm. In a particular embodiment, the thickness of the film, lightguide or lightguide region is less than 0.5 mm or, more specifically, less than 0.2 mm. In an alternative embodiment, the thickness of the film, lightguide or lightguide region is greater than 0.5 mm or, more specifically, at least 2 mm.

### Light Transmitting Material

In one embodiment, a lightguide or lightguide region is formed from at least one light transmitting material. In one embodiment, the lightguide is a film including at least one core region and at least one cladding region. Each of the at least one core region and the at least one cladding region includes at least one light transmitting material. The light transmitting material used within an embodiment may be a thermoplastic material, thermoset material, amorphous material, semi-crystalline material, crystalline material, cross-linked polymer, reinforced material, rubber, polymer, high transmission silicone, glass, composite, alloy, blend, silicone, polydimethylsiloxane, or one or more other suitable light transmitting materials, or a combination thereof. In another embodiment, the lightguide is a high performance film, such as those known in the display, printed electronics, and photovoltaic industry as having sufficient mechanical and optical properties. In one embodiment, the light transmitting material includes one or more of the following: polymethyl methacrylate, polyacrylate, cellulose derivatives (e.g., cellulose ethers such as ethylcellulose and cyanoethylcellulose, cellulose esters such as cellulose acetate), acrylic resins, styrenic resins (e.g., polystyrene), polyvinyl-series resins [e.g., poly(vinyl ester) such as poly(vinyl acetate). poly(vinyl halide) such as poly(vinyl chloride), polyvinyl alkyl ethers or polyether-series resins such as poly(vinyl methyl ether), poly(vinyl isobutyl ether) and poly(vinyl t-butyl ether)], polycarbonate-series resins (e.g., aromatic polycarbonates such as bisphenol A-type polycarbonate), polyarylate, polyacrylate, liquid crystalline polymer, polyimide, colorless polymide, polysulfone, polyetherimide, polyimide, polyphenyl oxide, polyvinyl fluoride (PVF), polyvinylidene fluoride (PVDF), ethylene vinyl acetate (EVA), polyester-series resins(e.g., homopolyesters, for example, polyalkylene terephthalates such as polyethylene terephthalate and polybutylene terephthalate, polyalkylene naphthalates corresponding to the polyalkylene terephthalates; copolyesters containing an alkylene terephthalate and/or alkylene naphthalate as a main component; homopolymers of lactones such as polycaprolactone), polyamide-series resin (e.g., nylon 6, nylon 66, nylon 610), urethane-series resins (e.g., thermoplastic polyurethane resins), elastomer, and copolymers of monomers forming the above resins [e.g., styrenic copolymers such as methyl methacrylate-styrene copolymer (MS resin), acrylonitrile-styrene copolymer (AS resin), styrene-(meth)acrylic acid copolymer, styrene-maleic anhydride copolymer and styrene-butadiene copolymer, vinyl acetate-vinyl chloride copolymer, vinyl alkyl ether-maleic anhydride copolymer]. Incidentally, the copolymer may be a random copolymer, a block copolymer, or a graft copolymer. In one embodiment, the light transmitting material includes a fluropolymer such as an amorphous fluoropolymer including interpolymerized units derived from vinylidene fluoride (VDF) and hexafluoropropylene (HPF) and optionally tetrafluoroethylene (TFE) monomers, VDF-chlorotrifluoroethylene copolymers, homo and copolymers based on fluorinated monomers such as TFE or VDF which do contain a crystalline melting point such as polyvinylidene fluoride (PVDF) or thermoplastic copolymers a TFE such as those based on the crystalline microstructure of TFE-HFP-VDF perfluoroalkoxy(PFA), fluorinated ethylene propylene (FEP), polytetrafluoroethylene (PTFE), ethylene tetrafluoroethylene (ETFE), or fluropolymer including monomers such as perfluoromethyl vinyl ether, perfluoropropyl vinyl ether, and perfluoro(3-methoxy-propyl) vinyl ether.

### Multilayer Lightguide

In one embodiment, the stretchable lightguide film includes at least two layers or coatings. In another embodiment, the layers or coatings function as one or more of the following: a core layer, a cladding layer, a tie layer (to promote adhesion between two other layers), as layer to increase flexural strength, a layer to increase the impact strength such as Izod, Charpy, Gardner, for example), and a carrier layer. In a further embodiment, at least one layer or coating includes a microstructure, surface relief pattern, light input coupling features lenses, or other non-flat surface features which redirect a portion of incident light from outside the lightguide to an angle within the lightguide that satisfies the total internal reflection condition for the lightguide. In another embodiment, the core material includes a methacrylate material and the cladding includes a silicone material.

### Core Region Including a Thermoset Material

In one embodiment, a thermoset material is coated onto a thermoplastic film. The thermoset material, in this embodiment, is the core material and the cladding material is the thermoplastic film or material. In another embodiment, a first thermoset material is coated onto a film including a second thermoset material. In this embodiment, the first thermoset material is the core material and the cladding material is the second thermoset material.

In one embodiment, an epoxy resin that has generally been used as a molding material may be used as the epoxy resin (A). In another embodiment, the thermosetting resin is a thermosetting silicone resin. In another embodiment, the thermosetting includes a silicone, polysiloxane, or silsesquioxane material. In a further embodiment, the thermosetting composition includes one or more of the following: an aluminosiloxane, a silicone oil containing silanol groups at both ends, an epoxy silicone, and a silicone elastomer. In another embodiment, the thermoset is a photopolymerizable composition. In another embodiment, the thermosetting resin includes a silsesquioxane derivative or a Q-containing silicone. In another embodiment, the thermosetting resin is a resin with substantially high light transmission.

### Optical Properties of the Lightguide or Light Transmitting Material

With regard to the optical properties of the stretchable optical lightguide film, the optical properties specified herein may be general properties of the lightguide, the core, the cladding, or a combination thereof, or they may correspond to a specific region (such as a light input region, or light output region), surface (light input surface, light output surface, diffuse surface, flat surface), and/or direction (such as measured normal to the surface or measured in the direction of light travel through the lightguide).

In one embodiment, the light transmitting material is used in one or more of the following: the strip, lightguide, lightguide region, optical element, optical film, core layer, cladding layer, and optical adhesive. In this embodiment, the light transmission material has an optical absorption (dB/km) less than one selected from the group: 50, 100, 200, 300, 400, and 500 dB/km for a wavelength range of interest. The optical absorption value may be for all of the wavelengths throughout the range of interest or an average value throughout the wavelengths of interest. The wavelength range of interest for high transmission through the light transmitting material may cover the solar light spectrum, the desired light output spectrum for the solar energy system, optical functionality requirements (such as matching the spectral sensitivity of a photovoltaic device or absorption spectrum of a solar thermal device), or a combination thereof. In one embodiment, the wavelength range of interest may be a wavelength range selected from the group: 250 nanometers (nm) 2700 nm, 250 nm-400 nm, 400 nm-700 nm, 300 nm-800 nm, 500 nm-900 nm, 500 nm-1100 nm, 300-450 nm, 350 nm-400 nm, 400 nm-900 nm, 450 nm-490 nm, 490 nm-560 nm, 500 nm-550 nm, 550 nm-600 nm, 600 nm-650 nm, 635 nm-700 nm, 650 nm-700 nm, 700 nm-750 nm, 750 nm-800 nm, 800 nm-1200 nm, 700 nm-2700 nm, 800 nm-2000 nm, and 1000 nm-2700 nm.

### Refractive Index Of The Light Transmitting Material

In one embodiment, the core material of the lightguide has a high refractive index and the cladding material has a low refractive index. In one embodiment, the core material has a refractive index (n_{D}) greater than one selected from the group: 1.3, 1.4. 1.5, 1.6, 1.7, 1.8, 1.9, 2.0, 2.1, 2.2, 2.3, 2.4, 2.5, 2.6, 2.7, 2.8, 2,9, and 3.0. In another embodiment, the refractive index (n_{D}) of the cladding material is less than one selected from the group: 1.1, 1.2, 1.3, 1.4, 1.5, 1.6, 1.7, 1.8, 1.9, 2.0, 2.1, 2.2, 2.3, 2.4, and 2.5.

### Mechanical Properties of the Stretchable Optical Lightguide

In one embodiment, the stretchable optical lightguide has low creep or tendency of the film material to move slowly or deform permanently under the influence of stresses. In one embodiment, the creep rate of the stretchable optical lightguide is less than one selected from the group: 8×10⁻⁵, 6×10⁻⁵, 4×10⁻⁵, 2×10⁻⁵, 1×10⁻⁵, 0.5×10⁻⁵, 0.1×10⁻⁵, 1×10⁻⁷, and 1×10⁻⁸ percent per hour when under a stress of 5 megapascals at 90 degrees centigrade. Typically, the higher the glass transition temperature of a polymer, the reduced creep for a given temperature. In one embodiment, the glass transition temperature of the stretchable optical lightguide is greater than one selected front the group: 100, 175, 150, 200, 250, 270, and 300 degrees centigrade.

Additionally, the molecular weight of the polymer of interest is known to affect its creep behavior. The effect of increasing molecular weight tends to promote secondary bonding between polymer chains and, thus, make the polymer more creep resistant. Similarly, aromatic polymers are even more creep resistant due to the added stiffness from the rings. Both molecular weight and aromatic rings add to a polymer's thermal stability, increasing the creep resistance of the polymer. In one embodiment, the molecular mass of the light transmitting material is larger than one selected from the group: 15,000, 20,000, 50,000, 100,00, 200,000, 300,000, 400,000, and 500,000 atomic mass units.

In one embodiment, the stretchable optical lightguide is pre-strained or strain-hardened. For example, in one embodiment, the film is pre-strained and the coupling features are added to the film after straining. In another embodiment, the coupling features are pre-formed to account for a base level of strain or creep. For example, the spacing of diffractive features could be made smaller, with the anticipation of stretching during end use, to expand beyond a base level (for example a non-linear stretch regime), to account for initial creep, or to dial in the exact pitch required to cover the angle of incidence range for solar application in a range of worldwide terrestrial locations.

In one embodiment, the Young's modulus of the stretchable optical lightguide film is one selected from the group: 0.01-5, 0.01-1, 0.01-2, less than 2, less than 3, less than 7, less than 10, and less than 30 Gigapascals. In one embodiment, the low Young's modulus allows the stretchable optical lightguide to strain (stretch) significantly when a small force is exerted. In another embodiment, the yield strength of the stretchable optical lightguide film is one selected from the group: greater than 1, greater than 5, greater than 10, greater than 20, greater than 50, greater than 100, and greater than 200 kilopascals. In one embodiment, the stretchable optical lightguide film has a high yield strength that enables the film to be stretched a significant amount before plastic deformation. In one embodiment, the stretchable optical lightguide film has anisotropic properties, such as, for example, a higher Young's modulus, a higher yield strength, and/or a lower creep in a first direction parallel to the plane of the film than a Young's modulus, yield strength, and/or creep in a second direction orthogonal to the first direction and parallel to the plane of the film.

### Output Coupling Strips

In one embodiment, the lightguide film is formed of a flexible sheet of film surrounded by a bounding edge. The sheet is folded upon itself such that portions of the bounding edge overlap, and an unfolded portion defining the body is left where the sheet is not folded upon itself. In this example, the sheet is formed with a number of discrete strips, such as an array of strips, extending from the unfolded body. Each strip terminates at the portions of the bounding edge which are to overlap. The strips are folded between their bounding edges and the body at folds such that at least some of the strips are bent into stacked relationship, with their bounding edges, in one embodiment, being at least substantially aligned, and also being prepared to define a substantially smooth and continuous surface (e.g., by polishing). In one embodiment, an output coupling system comprises the folded strips and a light collector.

### Relative Position Maintaining Element

In one embodiment, at least one relative position maintaining element substantially maintains the relative position of the strips in a fold region. In another embodiment, the relative position maintaining element is disposed adjacent a linear fold region of the array of strips such that the combination of the relative position maintaining element with the strips provides sufficient stability or rigidity to substantially maintain the relative position of the strips within the fold region during translational movements of the strips to create the overlapping collection of strips and the bends in the strips. The relative position maintaining element may be adhered, clamped, disposed in contact, disposed against a fold region or strip, or disposed between a fold region and a lightguide region. The relative position maintaining element may be a polymer or metal component that is adhered or held against the surface of the strips, lightguide region, or film at least during one of the translational steps. In one embodiment, the relative position maintaining element is a polymeric strip with planar or saw-tooth-like teeth adhered to either side of the film near the linear fold region. By using saw-tooth-like teeth, the teeth can promote or facilitate the bends by providing angled guides. In another embodiment, the relative position maintaining element is a mechanical device with a first clamp and a second clamp that holds the coupling lightguides in relative position in a direction parallel to the clamps parallel to the first fold region and translates the position of the clamps relative to each other such that the first linear fold region and the second linear fold region are translated with respect to each other to create overlapping coupling lightguides and bends in the coupling lightguides. In another embodiment, the relative position maintaining element maintains the relative position of the coupling lightguides in the fold region and provides a mechanism to exert force upon the end of the coupling lightguides to translate them in at least one direction.

### Coupling Features

In one embodiment, the stretchable optical lightguide film includes one or more coupling features in a light input, area configured to couple external solar light into the lightguide in a waveguide condition or to a material operatively coupled to the core region or lightguide film. Operatively coupling the light coupling feature to a region includes, without limitation: adding, removing, and/or altering material on the surface of the region and/or is within a volume of the region: disposing a material on the surface of the region or within the volume of the region; apply a material on the surface of the region or within the volume of the region; printing or painting a material on the surface of the region or within, the volume of the region; removing material from the surface of the region or from the volume of the region; modifying, a surface of the region or a region within the volume of the region; stamping or embossing a surface of the region or the region within the volume of the region; scratching, sanding, ablating, or scribing a surface of the region or the region within the volume of the region; forming a light coupling feature on the surface of the region or within the volume of the region; bonding a material on the surface of the region or within the volume of the region: adhering a material to the surface of the cladding region or within the volume of the cladding region; optically coupling the light coupling feature to the surface of the region or the region within the volume of the region: optically coupling or physically coupling the light coupling feature to the region by an intermediate surface, layer or material disposed between the light coupling feature and the region.

In one embodiment, the one or more light coupling feature is defined by a raised or recessed surface pattern or a volumetric region. Raised and recessed surface patterns include, without limitation, scattering material, raised lenses, scattering surfaces, pits, grooves, surface modulations, microlenses, lenses, diffractive surface features. holographic surface features, photonic bandgap features, nanophotonics, scattering mechanisms, multi-layer optics, reflective metal, gradient index, subwavelength optics, wavelength conversion materials, holes, edges of layers (such as regions where the cladding is removed from covering the core layer), pyramid shapes, prism shapes, and other geometrical shapes with flat surfaces, curved surfaces, random surfaces, quasi-random surfaces and combination thereof. In one embodiment the volumetric scattering regions within the light coupling feature may include dispersed phase domains, voids, absence of other materials or regions (gaps, holes), air gaps, boundaries between layers and regions, and other refractive index discontinuities within the volume of the material different than co-planar layers with parallel interfacial surfaces. In one embodiment, one or more stretchable optical lightguides include light coupling features in a plurality of regions. In one embodiment, the solar system, including the stretchable optical film lightguide, the stretchable optical film lightguide, or a region (such as an input region) include light coupling features on and/or within one outer surface, two outer surfaces, two outer and opposite surfaces, an outer surface and at least one region disposed between the two outer surfaces, within two different volumetric regions substantially within two different volumetric planes parallel to at least one outer surface or light emitting surface or plane, and/or within a plurality of volumetric planes. More than one type of light coupling feature may be used on the surface, within the volume of a lightguide or lightguide region, or a combination thereof.

In one embodiment, the light coupling feature is substantially directional and includes one or more of the following: an angled surface feature, curved surface feature, rough surface feature, random surface feature, asymmetric surface feature, scribed surface feature, cut surface feature, non-planar surface feature, stamped surface feature, molded surface feature, compression molded surface feature, thermoformed surface feature, milled surface feature, extruded mixture, blended materials, alloy of materials, composite of symmetric or asymmetrically shaped materials, laser ablated surface feature, embossed surface feature, coated surface feature, injection molded surface feature, extruded surface feature, and one of the aforementioned features disposed in the volume of the lightguide. For example, in one embodiment, the directional light coupling feature is a 100 micron long 45 degree angled facet groove formed by thermal embossing the lightguide film that substantially directs a portion of the light incident at 40 degrees from the normal in air to an angle greater than 50 degrees from the normal within the stretchable optical lightguide

In one embodiment, at least one light coupling feature is an array, pattern or arrangement of a wavelength conversion material selected from the group: a fluorophore, phosphor, a fluorescent dye, an inorganic phosphor, photonic bandgap material, a quantum dot material, a fluorescent protein, a fusion protein, a fluorophores attached to protein to specific functional groups, quantum dot fluorophores, small molecule fluorophores, aromatic fluorophores, conjugated fluorophores, and a fluorescent dye scintillators, phosphors such as Cadmium sulfide, rare-earth doped phosphor, and other known wavelength conversion materials. In one embodiment, the solar energy system is a luminescent solar concentrator including an optical film-based lightguide.

In one embodiment, the light coupling feature is a protrusion from the film-based lightguide material or layer. In another embodiment, the light coupling feature is a recessed region within the film-based lightguide layer. The pattern or arrangement of light coupling features may vary in size, shape, pitch, location, height, width, depth, shape, and/or orientation, in the x, y, and/or z directions.

### Coupling Feature Changes When Film is Stretched

In one embodiment, the optical properties of the light coupling features change when the film is stretched (stress is increased in one or more directions and a dimension of the film is increased) or relaxed from stretching (contracted, shortened, shrunk, or reduced strain in one or more directions such that a dimension of the film is decreased, riot necessarily reducing the strain to zero). In one embodiment, the physical features and optical properties of one or more coupling features changes when the film is stretched or relaxed. The change in optical properties can include, for example, directing light incident at a first incident angle that was not coupled into the film to a redirected angle that satisfies the total internal reflection condition within the stretched optical lightguide film. The change in optical features can result from the change in physical features from the stretching or contracting such as a change in pitch, form, shape, orientation, density, refractive index, and/or size to the coupling features. The resulting change in optical properties compensate for a change in the angle at which the light contacts the lightguide film and/or interacts with the coupling feature. In one embodiment, the stretchable optical lightguide film is resilient and when the film is relaxed (stress is reduced), the light coupling features return to a previous position. For example, in one embodiment, the stretchable optical lightguide film is stretched to increase the input coupling efficiency into the film as the sun traverses the sky from east to west and the film is relaxed to receive light from the east the following day.

In one embodiment, the stretchable optical film includes coupling features that are designed to coupling light into a lightguide condition within the core of the film. In this embodiment, when the angle of incidence changes, the film is stretched and the light is tracked due to the coupling features changing in the thickness direction of the film due to the stretching of the stretchable optical lightguide film. In another embodiment, one or more optical properties of the coupling features change and track the sun due to changes in the thickness direction in combination with one or more changes in spacing and/or feature sizes in an in-plane direction orthogonal to the thickness direction.

### Feature Coupling Efficiency and Film Coupling Efficiency

In one embodiment, the coupling features have a feature coupling efficiency (the percentage of the solar spectrum of light incident upon the coupling features at a specific angle that is coupled into a waveguide condition in the lightguide film) greater than one selected from the group: 2%, 5%, 10%, 15%, 20%, 30%, 40%, 50%, 60%, 70%, 80%, and 90%. In another embodiment, the stretchable optical lightguide film has a film coupling efficiency (the percentage of the solar spectrum of light at a specific angle of incidence that is coupled into a waveguide condition in the lightguide film across the input area including the coupling features, which may include regions without coupling features) greater than one selected from the group: 2%, 5%, 10%, 15%, 20%, 30%, 40%, 50%, 60%, 70%, 80%, and 90%. In one embodiment, the solar energy system tracks the sun as the sun moves across the sky and the average feature coupling efficiency, film coupling efficiency, and/or optical efficiency of the solar energy system is greater than one selected from the group: 2%, 5%, 10%, 15%, 20%, 30%, 40%, 50%, 60%, 70%, 80%, and 90%.

### Angular Input Coupling Bandwidth

The angular input coupling bandwidth of the light coupling features includes the range of angles around an incident design angle of light that is coupled into the lightguide condition. In one embodiment, the light coupling features of the stretchable optical film. redirect light incident from an angular range at a fixed stretch position from one selected from the group: −5° to +5°, −10° to +10°, −20° to +20°, −30° to +30°, −45° to +45°, and −60° to +60° from a fixed input design angle in air. For example, in one embodiment, the stretchable optical film is stretched to a first stretch position to capture light from a first incident design angle of +30 degrees from the normal and the coupling features have an angular input coupling bandwidth of −20° to +20′ and capture light (redirect light into a lightguide condition) from +10 degrees to +50 degrees. This input coupling bandwidth can help collect light on cloudy days, for example when the angle of incidence is over a range of angles. The light redirected (coupled into the lightguide) may also be dependent upon the polarization and/or wavelength of the incident light and the light coupling features may similarly be optimized for a design wavelength and/or design polarization angle or state. In one embodiment, the light coupling features of the stretchable optical film redirect light of a wavelength bandwidth greater than one selected from the group: 20 nm, 50 nm, 100 nm, 200 nm, 300 nm, 400 nm, 500 nm, 600 nm, 700 nm, 800 nm, 900 nm, 1000 nm, 1200 nm, and 1500 nm, incident at a first design angle from a first design wavelength in air. For example, in one embodiment, the stretchable optical film is stretched to a first position to capture light from a first incident design wavelength of 700 nm at a first incident angle from the normal and the coupling features collect light (redirect light to a waveguide condition) from 400 nm to 1000 nm.

### Angular Input Adjustable Range

In one embodiment, the stretchable optical lightguide film peak incidence angle (the incident angle with the highest peak film coupling efficiency) changes from a first peak incidence angle to a second peak incidence angle when the film is stretched or shortened for a first wavelength spectrum. For example, in one embodiment, the stretchable optical lightguide film includes light coupling features having a blazed diffraction grating with a first pitch, p1, in a first stretched state (pulled to a light input area of 1 meter for example), with a peak incidence angle of 50 degrees from the normal to the film for the solar spectrum from about 250 nm-2500 nm. When the film is stretched to a width of 1.5 meters, the pitch increases to a second pitch, p2, larger than the first pitch and the peak angle of incidence is 30 degrees from the normal. The amount of stretching needed to optimize the film coupling efficiency can be determined by a number of factors, such as the orientation of the stretchable lightguide film, the azimuthal angle of the sun, the zenith angle of the sun, the change in solar spectrum as the sun crosses the sky, the optical transmission spectrum of the light transmitting material of the film, the design of the coupling features, the number and design of coupling feature regions and stretchable optical lightguide films, the relationship between stress and strain of the light transmitting material and coupling features, the bandgap of the photovoltaic cell (if used), and the feedback from other system components (such as electrical or optical feedback components from a photovoltaic system, temperature sensors from a solar thermal system, light sensors from an illumination fixture or system, etc.). In one embodiment, the angular peak range, the difference between the first peak incidence angle to the second peak incidence angle for the stretchable optical lightguide film, is greater than one selected from the group: 5°, 10°, 20°, 30°, 40°, 50°, 60°, 70°, 80°, 90°, 110°, 110°, 120°, 130°, 140°, 150°, 160°, and 170°.

### Strips On Opposite Sides With Reflector Or Collector

In one embodiment, the stretchable optical lightguide film includes a first set of strips extending from a first end positioned to direct the light output to a first light collector, and a second set of strips extended from a second end positioned to direct light output to a second light collector or a reflective film. In one embodiment, the second light collector is a reflective film that redirects light back through the second set of strips, into the coupling feature region where a portion of the light passes through the first set of strips toward the first light collector. In one embodiment, the reflector at the second set of strips is a retroreflective film such as a corner cube retroreflective film. In another embodiment, the reflector is a specular mirror film. In one embodiment, light incident on the stretchable optical lightguide film from a first range of angles is directed by coupling features to a first out-coupling system including a first light collector at a first side of the lightguide film and light from a second range of angles different from the first range of angles is directed by the coupling features to a second out-coupling system including a second light collector at a second side of the lightguide film opposite the first side.

### Multiple Lightguide Layers

In one embodiment, the solar energy system includes a plurality of stretchable optical lightguides. In one embodiment, the plurality of stretchable optical lightguides are stacked above each other. In another embodiment, a first stretchable optical lightguide in a stack is configured to have a high film coupling efficiency for a first wavelength bandwidth and a second stretchable optical lightguide in the stack is configured to have a high film coupling efficiency for a second wavelength bandwidth different than the first wavelength bandwidth. For example, in one embodiment, a first stretchable optical lightguide in a stack is designed to efficiency couple incident light from a wavelength range from 400 mm to 900 nm into the core of the lightguide to be directed toward the strips and coupled out of the stacked strip ends to a silicon-based photovoltaic cell, and a second stretchable optical lightguide in the stack is designed to efficiency couple incident light from a wavelength range from 1000 nm to 1700 nm into the core of the second lightguide to be directed toward the strips and coupled out of the stacked strip ends to an indium gallium arsenide based photovoltaic cell.

### Tension Adjustment Mechanism

In one embodiment, the tension adjustment mechanism adjusts the tension in the stretchable optical lightguide film as the sun moves across the sky to increase the feature coupling efficiency film coupling efficiency, and/or solar energy system efficiency. The tension adjustment mechanism may be automatic, manual, active, or passive. In one embodiment, a stretchable optical lightguide film is clamped or held at one end across a side with a clamping bar or rod and an actuator operatively coupled to the bar or rod pulls the bar or rod such that the film is stretched elastically. Similarly, the actuator may move the bar or rod toward the film such that the tension on the film is reduced and the resilience of the film causes the coupling features to contract. In one embodiment, the solar energy system includes one or more of the following actuators: a linear actuator, a hydraulic actuator, a piezoelectric actuator, an electrostatic actuator, an electrical motor, a pneumatic actuator, an automatic actuator, a manual actuator, an active actuator, a passive actuator, and an active and passive actuator. In one embodiment, the solar energy system includes a stretchable optical lightguide film operatively coupled on at least one end or region to a roller that is mechanically rotated by an electrical motor to increase or decrease the tension or stress on the film.

### Coupling Feature Region

The stretchable optical lightguide film includes a coupling feature region defined by a plurality of coupling features. In one embodiment, a size of the coupling feature region increases in the stretch direction when the film is stretched. In certain embodiments, the size of the coupling feature region in a second direction orthogonal to the stretch direction decreases when the film is stretched. This can occur when the film is not constrained or held in the second direction and is often called “neck-in.” In one embodiment, one or more physical aspects of the light coupling features are designed to account for dimensional change in the film in a direction orthogonal to the stretch direction.

The coupling feature may have linear, circular, square, two-dimensional, or three-dimensional features. In one embodiment, a stretchable optical lightguide film is substantially circular and the coupling features are three-dimensional conical or cylindrical surface protrusions extending from the film surface such that when the film is stretched from the perimeter regions of the circular film, the pitch or separation between the coupling features increases in a radial direction.

In one embodiment, an increase in the dimension of the coupling feature region in the stretch direction when the film is stretched increases the size at the solar energy device. In another embodiment, the dimension of the solar energy device in the stretch direction does not substantially increase when the stretchable optical lightguide filth is stretched; however, when the film is relaxed or constrained less than its maximum state for the device, there are inactive areas in the stretch direction that do not include light coupling features. Because in solar energy devices one would normally like to utilize all of the area of the device exposed to solar radiation to capture light, the device can be configured to position the stretched region beneath the active, light receiving area. In one embodiment, a portion of the coupling region is rolled beneath itself when stretched such that the area of the stretchable optical lightguide film including coupling features that receives light remains substantially the same.

For example, in one embodiment a rectangular shaped stretchable optical lightguide film is clamped at a first edge and is rolled around a cylindrical tension rod toward the opposite edge and is clamped to a second bar attached to an actuator at the second edge opposite the first edge, underneath the coupling feature region. In this example, when the actuator pulls the clamped first end, the cylindrical tension bar provides uniform tension and the film is stretched such that the coupling feature region extends around the tension rod and partly beneath the film. In this example, the area of the stretchable optical lightguide film that receives the light is not substantially reduced due to the stretching because the stretch region is curved beneath the light receiving area. In one embodiment, the coupling features are extended to one or more regions on both sides of one or more curved regions such that the stretchable optical lightguide film, in effect, has multiple lightguide layers (one below another) where the lower layer or region can receive light that is transmitted through upper layer or region. In another embodiment, when the stretchable optical lightguide film is under reduced stress, the coupling feature region and film extends in the in-plane direction orthogonal to the stretch direction around the edges of the device (across rollers for example) such that when the film is stretched in the stretch direction, the neck-in of the film allows the coupling feature region to fully occupy the area exposed to sunlight in the reduced stress state.

### Frame Structure

In one embodiment, a solar energy system includes a frame structure that supports one or more elements of the solar energy system including one or more stretchable optical lightguide films, one or more tension adjustment mechanisms, output coupling strips, protective covers or lenses, support plates, electrical components, feedback components, and other mechanical, electrical, and/or optical components of the solar energy system.

### Covers, Supports, and Lenses

In one embodiment, the solar energy system includes one or more support layers or plates that support the stretchable optical lightguide film and reduce or eliminate film sagging. Film sagging can occur when the physical weight of the film causes a distortion in the shape of the film, even while under a specific level of tension. For example, in one embodiment, the stretchable optical lightguide film would sag significantly under its own weight at a desired stress level and a rigid support plate beneath the film prevents the sag and creates a uniform acceptance angle for coupling light into the lightguide because the lightguide is not curved. Furthermore, in this embodiment, the lower support plate also provides protection from external elements. Similarly, an upper rigid protective plate may provide protection from the elements such as rain, hail, and/or wind. The upper rigid protective plate may also provide optical functionality through light redirecting features. For example, in one embodiment, the upper protective plate includes an array of linear lenticular structures that redirect light over a range of incident angles. In one embodiment, the optical functionality includes optically redirecting light by one or more of the following: refraction, reflection, total internal reflection, and diffraction. In another embodiment, the optical redirection features work in conjunction with the coupling features such that the optical redirection features pre-condition the angular extent of the incident light reaching the coupling features and the efficiency of the solar energy system, film coupling, and/or coupling features is increased relative to a system with a protective upper plate without the optical functionality. The optical redirection features may include, without limitation, one or more of the following: microlens arrays, refractive features, diffractive features or gratings, holographic features. Fresnel lens features, prismatic features and other surface or volumetric light redirecting features. In one embodiment, the optical features providing optical functionality are disposed on the upper (outer) surface of the upper protective plate. In another embodiment, the optical redirection features are positioned on the lower (inner) surface of the upper protective plate. In one embodiment, at least one of the stretchable optical lightguide film, a cladding layer on the stretchable optical lightguide film, and the surface of the upper or lower support or protective plate includes an anti-block additive or other friction reducing features (including, but not limited to, optical features, material surface tensions and the resulting interfacial tensions). By reducing the friction on the lower support plate, for example, the stretchable optical lightguide film can be supported in a substantially flat for curved if desired) shape without requiring a large stress to be applied in order to stretch the film. Furthermore, in this example, less stress is required to keep the stretchable optical lightguide film substantially flat in the relaxed or less stretched state. This reduction in stress required for the stretched and/or un-stretched, contracted, or less stretched state can reduce the long term creep of the film. In one embodiment, the sag in an unsupported stretchable optical lightguide film is predicted or pre-measured and the coupling features are designed to compensate for the sag. In another embodiment, the stretchable optical lightguide film is encapsulated between the upper protective plate and the lower support plate and sidewalls plates or materials with a sealant to protect the lightguide film from air and moisture.

### Lower Reflective Layer

In one embodiment, a reflective film or layer is positioned on the side of the stretchable optical lightguide film that is not directly exposed to solar radiation. In one embodiment, the lower reflective layer provides light recycling to increase the amount of light incident on the stretchable optical lightguide film. In another embodiment, the solar energy system is designed to collect light when the sun is in a first angular range by direct coupling into the stretchable optical lightguide film and is designed to collect light when the sun is in a second angular range after the incident light passes through the stretchable optical lightguide film once and is reflected off of the lower reflective layer.

In one embodiment, the reflective layer is a specular reflective layer such as, for example, an aluminized polyethylene terephthalate film or giant birefringent optical film with multiple layers. In another embodiment, the reflective layer is a diffusely reflecting layer such as a polyethylene terephthalate film defining voids and/or titanium dioxide domains. In one embodiment, the lower support plate is a reflective aluminum plate which may include additional coatings to provide increased reflectivity.

### Feedback Mechanism

In one embodiment, the solar energy system includes one or more feedback mechanisms to provide input for controlling the tension or stress applied to the stretchable optical film to efficiently track the sun. In one embodiment, the solar energy system includes one or more of the following feedback mechanisms; a tension feedback mechanism, a positional feedback mechanism, an optical feedback mechanism, and an electrical feedback mechanism.

### Tension Feedback Mechanism

In one embodiment, the solar energy system includes a tension feedback mechanism that monitors the tension or stress of the stretchable optical lightguide film to facilitate increasing or decreasing the tension or stress based at least in part on the measured or predicted location of the sun. In one embodiment, the stress or tension applied to the stretchable optical lightguide film is a direct or referenced relationship to the efficiency of the is coupling features and/or the film coupling efficiency for a measured or predicted solar angle.

### Positional Feedback Mechanism

In one embodiment, one or more coupling feature regions of the stretchable optical lightguide film includes a positional feedback mechanism that provides relative positional information for one or more coupling feature regions (or regions near coupling features) relative to each other or relative to a reference point. The positional feedback mechanism may include a distance or location measurement device including, without limitation, an optical feedback rail, laser ranging, and/or rotational gauges coupled to the film.

### Optical or Electrical Feedback Mechanism

In one embodiment, the solar energy system includes an optical feedback mechanism that provides information related to the optical efficiency of one or more coupling features, the film coupling efficiency, and/or the solar energy system efficiency. For example, in one embodiment, the photovoltaic cell positioned at the ends of the output coupling strips is utilized as a photodetector. The electrical output of the solar energy system is monitored to continuously adjust the tension or stress on the stretchable optical film to achieve the optimum film coupling efficiency and, thus, the optimum optical output at the earls of the strips. In another embodiment, a photodetector optical feedback mechanism is optically coupled to the lightguide or strips and optimizes the film coupling efficiency by providing feedback to the controller for adjusting the stress or tension on the stretchable optical lightguide film. In a further embodiment, a light sensor positioned in a room detects the illumination from the solar energy system providing daylighting illumination and provides illumination information to the solar energy system to enable the system to control the tension or stress on the stretchable optical lightguide film to increase, decrease or optimize the illumination provided by the device.

### Film Creep Reduction

In order to maintain the ability to adjust the tension to achieve the desired range of change in the coupling features, in one embodiment the stretchable optical lightguide film has a low level of creep. Optical films may strain and creep in a non-biaxial manner. As used herein, the term “creep” refers to accumulated plastic deformation of a film, or a change in length of a film, that does not reverse or disappear when forces that act to stretch the film are removed.

According to certain embodiments, the film is reinforced with fibers or other long reinforcement elements to reduce or eliminate film creep and maintain overall control over the film dimensions. Yarns of glass fiber, carbon fiber, ceramic fiber, plastic, steel, composite and/or other suitable materials, are used in one or more regions of the film.

Some embodiments provide for improving the problems associated with creep by increasing the tension or otherwise adjusting the coupling features. This adjustment can be static (applied on installation and possibly other occasions), quasi-static, or dynamic. Examples of quasi-static adjustment include, without limitation, adjustment to compensate for long-time-constant variations, such as mechanical creep and wear, seasonal variations, thermal expansion, and angular-position-dependent strain from gravity and actuator loads. Examples of dynamic adjustment include, without limitation, compensating for higher frequency loads, such as wind loads, flutter, or mechanical vibrations or oscillations.

The lifetime of a film may be dictated by any combination of at least three factors: 1) creep, 2) UV and environmental damage to the bulk material, and 3) environmental damage to the material surface. A solar energy system design may be configured such that these three factors are considered and the system has a longer lifetime.

### Mechanical Compensation for Film Creep

In some embodiments, the tension or stress on the optical film is reduced or eliminated during particular time periods. For example, in one embodiment, the tension or stress on the film is reduced or eliminated overnight when the sun is not illuminating the device. By reducing the time the film is exposed to stress or strain, the creep is reduced. In another embodiment, overcast and or dark/rainy days, where the energy output of the system may be reduced. the tension or stress on the film may be reduced to minimize long term creep.

### Solar Thermal Solar Energy System

In one embodiment, the solar energy system directs light into a lightguide and through the output coupling strips and into a light absorbing region that provides heat to a solar thermal system. Solar thermal systems include, without limitation, systems where a fluid, liquid, or molten material circulates to a heat converting or transferring element, such as a heat exchanger in a hot water tank, to provide hot water in a building, or a steam generator to generate electricity.

### Daylighting Solar Energy System

In one embodiment, the solar energy system directs light into a lightguide and through the output coupling strips and into a light emitting region of an illumination fixture that provides illumination. The solar energy system may further include lightguide components such as one or more optical fibers positioned to receive light from the output coupling strips and distribute the light to one or more light emitting fixtures that provide light from the solar energy system as daylighting illumination, These fixtures may also include electroluminescent illumination, such as for example a light emitting diode light source for nighttime use. In one embodiment, the strips extend from the solar radiation light receiving stretchable optical lightguide film to the light fixture component of the solar energy daylighting system within the interior of the building or area to be illuminated.

### Orientation of the Solar Energy Device

In one embodiment, the solar energy device includes a stretchable optical lightguide film oriented substantially horizontally. In one embodiment, the solar energy device includes a stretchable optical lightguide film oriented substantially vertically, such as, for example, in a building integrated photovoltaic solar energy device incorporated into window glazing. In another embodiment, the solar energy device includes a stretchable optical lightguide film oriented facing southward at a first orientation angle when employed in the northern hemisphere and facing northward at a second orientation angle when employed in the southern hemisphere. In one embodiment, the optimum orientation angle depends on the latitude of the system and can be chosen to maximize solar collection as is known with solar photovoltaic systems and solar thermal systems. In another embodiment the orientation of the stretchable optical lightguide film is not the southward or northward in order to have a higher collection efficiency using particular optics for the coupling features and optionally optical features on a protective plate or other layer in the system.

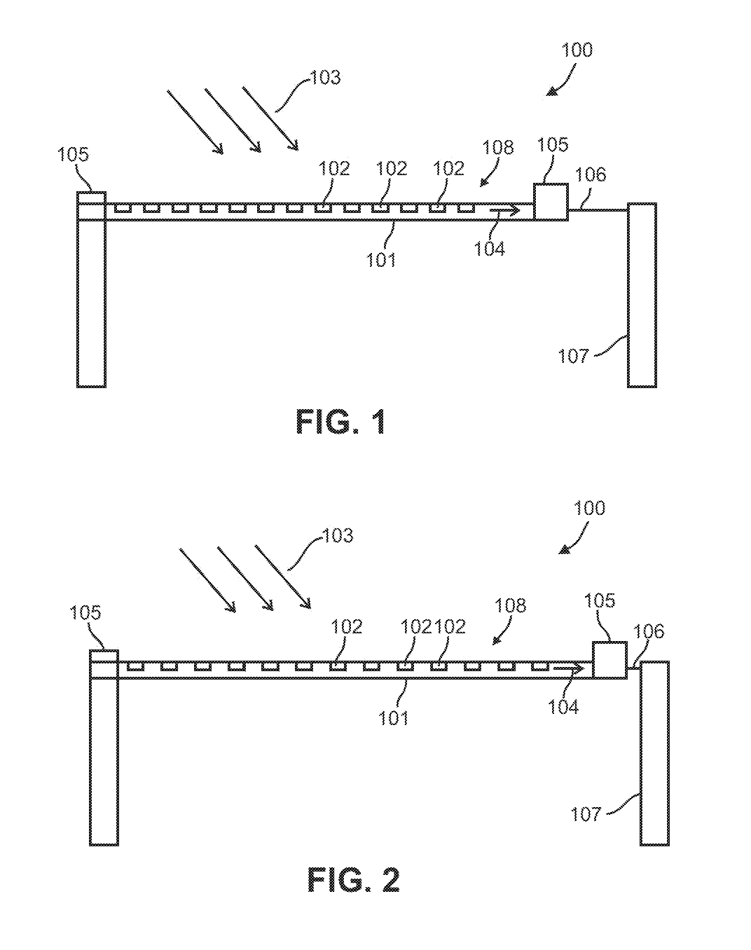

Referring to FIGS. 1-5, a solar energy system 100 includes an optical lightguide film 101 made of a suitable material that allows the lightguide film 101 to stretch and contract or shrink as desired to facilitate coupling light 103 into the lightguide film 101 and enhance a total internal reflection transfer of the light 103 within the lightguide film 101. In certain embodiments, one or more coupling features 102 are operatively coupled to the lightguide film 101 to effectively couple in light 103 from a given angle. As shown in FIGS. 1 and 2, in one embodiment, a plurality of coupling features 102 are formed on a surface of the lightguide film 101 and/or at least partially within the lightguide film 101. The light 103. that is coupled into the lightguide film 101 travels, as represented by arrow 104 in FIGS. 1 and 2, via total internal reflection to an out-coupling system 105 that is operatively coupled to a photovoltaic cell or other suitable light collector or harvesting mechanism.

A body 108 of the lightguide film 101 is kept in tension by a suitable tension adjustment mechanism 106 that is attached to a frame structure 107. The tension adjustment mechanism 106, the frame structure 107, and/or an external mechanism can be adjusted to change the tension in the lightguide film 101. FIG. 2 shows a change in an angle at which the light 103 contacts the lightguide film 101, for example at a different time of day. The tension adjustment mechanism 106 stretches the lightguide film 101 to a different length resulting in a change in form, shape, orientation, density, refractive index, and/or size to the coupling features 102 to facilitate compensating for a change in the angle at which the light 103 contacts the lightguide film 101. This results in coupling at least a portion of the light 103 into the lightguide film 101 such that the light 103 travels through the lightguide film 101 for collection. In one embodiment, the out-coupling system 105 may include a suitable strip-based coupler, such as the strip-based coupler described in International Application No. PCT/US2008/079041, entitled “Light Coupling Into Illuminated Films,” having an international filing date of Oct. 7, 2008, or any other suitable mechanism or method.

In one embodiment, the lightguide film 101 is formed of a flexible sheet of film surrounded by a bounding edge. The sheet is folded upon itself such that portions of the bounding edge overlap, and an unfolded portion defining the body 108 is left where the sheet is not folded upon itself. In this example, the sheet is formed with a number of discrete strips 112 extending from the unfolded body 108, and the strips 112 each terminate at the portions of the bounding edge which are to overlap. The strips 112 are folded between their bounding edges and the body 108 at folds such that at least some of the strips 112 are bent into stacked relationship, with then bounding edges, in one embodiment being at least substantially aligned, and also being prepared to define a substantially smooth and continuous surface (e.g., by polishing).

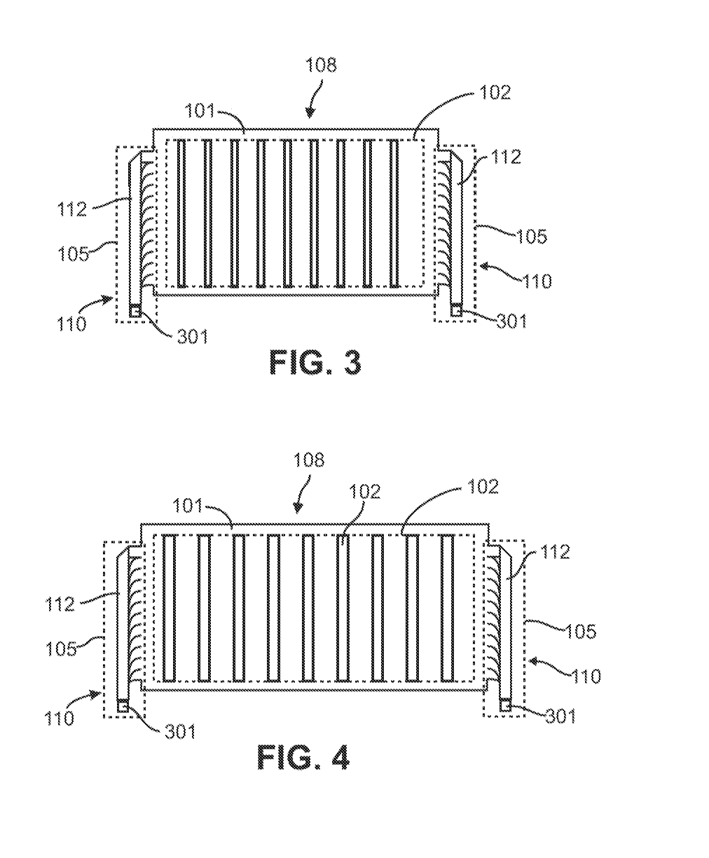

FIG. 3 shows a top view of one embodiment of the strip-based coupler 110 used for solar collection with the lightguide film 101. The lightguide film 101 is patterned with coupling features 102 that direct light towards the out-coupling system 105 based on folded strips 112 of the lightguide film 101. The strips 112 are optically coupled to the body 108. In certain embodiments, the strips 112 are angled or tapered to improve system efficiency. The light travels through the out-coupling system 105 into a light collector 301 such as photovoltaic cell. In FIG. 4, the lightguide film 101 is stretched so that the coupling features 102 change in form, shape, orientation, density, refractive index, and/or size for more efficient light capture. In certain embodiments, the strip-based couplers 110 are generally rigid and resist significant distortion when the lightguide film 101 is stretched. In one embodiment, the strips 112 are fixed or held rigidly within one or more frame members of the out-coupling system 105. In a particular embodiment, one or more out-coupling systems 105 are positioned along one or more sides of the lightguide film 101. Further, although in the embodiments described herein the lightguide film 101 is rectangular, in alternative embodiments the lightguide film 101 has any suitable two-dimensional geometric shape including, without limitation, a hexagon, a circle, or another suitable polygon shape or a suitable three-dimensional shape. As shown in FIGS. 3 and 4, the lightguide film 101 includes the body 108 and the strips 112 continuous with the body 108. In certain embodiments, a lower refractive index cladding region may be operatively coupled on one or more of the surfaces of the lightguide film 101.

In one embodiment, the stretchable lightguide film 101 is patterned with additional material of a different elastic modulus. The additional material may support the lightguide film 101. For example, a lightguide film 101 that is low modulus and prone to creep may be supported by a higher elastic modulus frame that ensures structural integrity over time. Furthermore, an additional material may be patterned to constrain the distortion of the coupling features 102 when a different tension is applied within the lightguide film 101. Moreover, the coupling features 102 may be a combination of materials that may distort, translate, decouple or otherwise change to help optical coupling by adjusting the tension in the lightguide film 101.

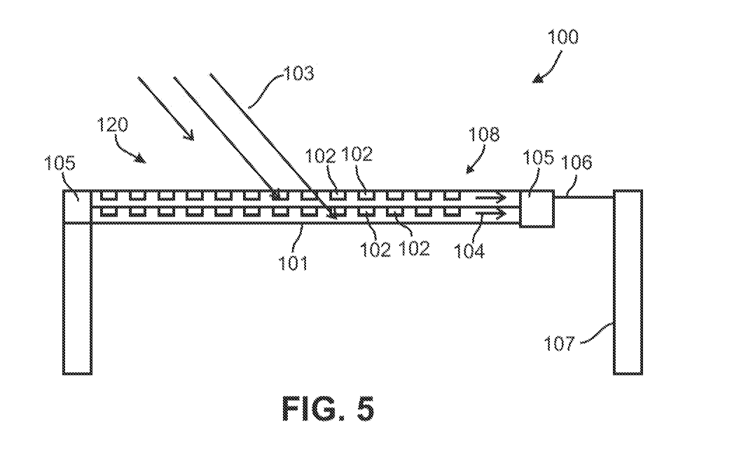

Referring further to FIG. 5, in one embodiment, solar energy system 100 includes a plurality of lightguide films 101 that may or may not be coupled to adjacent lightguide films 101, to form a layered lightguide film 120. In a particular embodiment, one or more additional layers (not shown) may be positioned between adjacent lightguide films 101 to facilitate capturing light that is not coupled by the lightguide film 101 forming the outer lightguide layer. Further, various lightguide layers may be optimized for colors and/or angular ranges. The coupling features 102 on the various lightguide layers may be spatially aligned or offset so that a given light ray may interact with each coupling feature 102 in order to couple the light into the layered lightguide film 120. The coupling features 102 may be patterned on, for example, a first or top layer, a second or bottom layer, and/or within the layered lightguide film 120.

In certain embodiments, the coupling features 102 may include at least one of the following: refractive optics, diffractive optics, nanophotonics, scattering mechanisms, multi-layer optics, reflective metal, gradient index and subwavelength optics. For example, a pitch of a blaze grating may change with the stretching of the lightguide film 101 to improve the in-coupling at a given light angle. The body 108 may measure more than 1 foot in length, although in certain embodiments the body 108 may measure less than one foot in any dimension or may have one or more dimensions substantially greater than 1 foot. Further, the supports 107 may suspend the lightguide film 101 at any suitable height above a support surface, such as a ground surface or a roof surface. For example, the frame structure 107 may suspend the lightguide film 101 at a height above the support surface chosen from: 1 millimeter (mm), 1 centimeter (cm), 1 meter (m), 2 m, 5 m and 8 m. In other embodiments, the frame structure 107 may suspend the lightguide film 101 at any suitable height above the support surface. In one embodiment, the lightguide film 101 is suspended by the frame structure 107 at a height sufficient to allow farm equipment to travel underneath the lightguide film 101 suspended over crop fields, for example. In certain embodiments, the lightguide film 101 may be optimized to collect light that is not efficiently collected in photosynthesis green light). In certain embodiments, the lightguide film 101 includes layers of inorganic film, which have been stacked, laminated or co-extruded together.

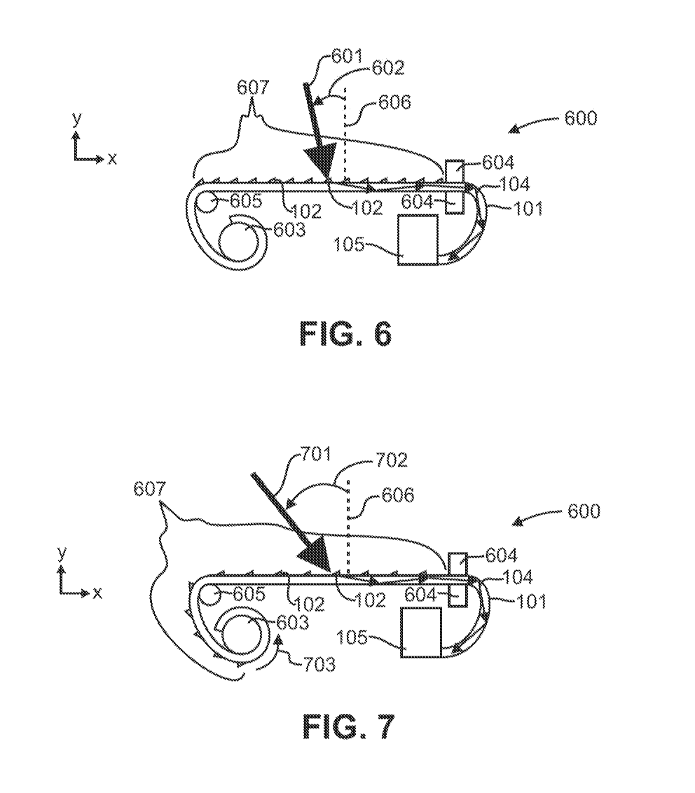

In one embodiment, the solar energy system 100 is utilized to collect light. In this embodiment, the lightguide film 101 including one or more coupling features 102 is stretched or contracted in one or more directions, as desired, to optically couple light into the lightguide film, FIG. 6 is a cross-sectional side View of one embodiment of a solar energy system 600 including a stretchable lightguide filth 101 with coupling features 102 positioned on the surface of the lightguide film 101. The out-coupling system 105 is positioned behind the coupling feature region 607 of the lightguide film 101 defined by the coupling features 102. Light 601 arriving from a first incident angle 602 from a direction 606 normal to the film is redirected by the coupling features 102 into a lightguide condition where the light propagates in a direction represented by arrow 104 within the lightguide film 101 and into the out-coupling system 105. In this embodiment, the lightguide film 101 is held by one or more clamps 604 near the out-coupling system 105. The lightguide film 101 is wrapped around a portion of a tension rod 605 toward the end of the lightguide film 101 near the tension adjustment mechanism 603. The tension adjustment mechanism 603 in this embodiment includes a rod operatively connected to a motor (not shown) that can rotate the rod to stretch the lightguide film 101. The lightguide film is operatively coupled to the tension adjustment mechanism 603 such that when the rod rotates in a first rotational direction (counterclockwise as shown in FIG. 7), the stress on the lightguide film 101 increases and the lightguide film is stretched in a stretch direction (-x direction as shown in FIG. 6).

FIG. 7 is a cross-sectional side view of the solar energy system 600 of FIG. 6 with the tension adjustment mechanism 603 rotated in the clockwise direction 703 to stretch the stretchable lightguide film 101. This stretching elongates the length of the stretchable lightguide film 101 and the length of the coupling feature region 607 such that the separation distance between the coupling features 102 increases. The increase in the pitch, or separation between the coupling, features 102, redirects light 701 arriving from the sun at a second incident angle 702 (different from the first incident angle 601 from FIG. 6 because the sun has traversed across the sky to a new position) from a direction 606 normal to the lightguide film into a lightguide condition where the light propagates in a direction represented by arrow 104 within the lightguide film 101 and into the out-coupling system 105, in this embodiment, by designing the lightguide film 101 to fold or bend under itself, the solar energy system 600 maintains a large area of exposure (the area of the coupling feat region exposed to incident light) when the film is in a lower strain state (FIG. 6 or a higher strain state (FIG. 7) since in the lower strain state, the length in the x direction of the coupling feature region 607 exposed to incident light is not reduced as seen when comparing the solar energy system of FIGS. 1 and 2.

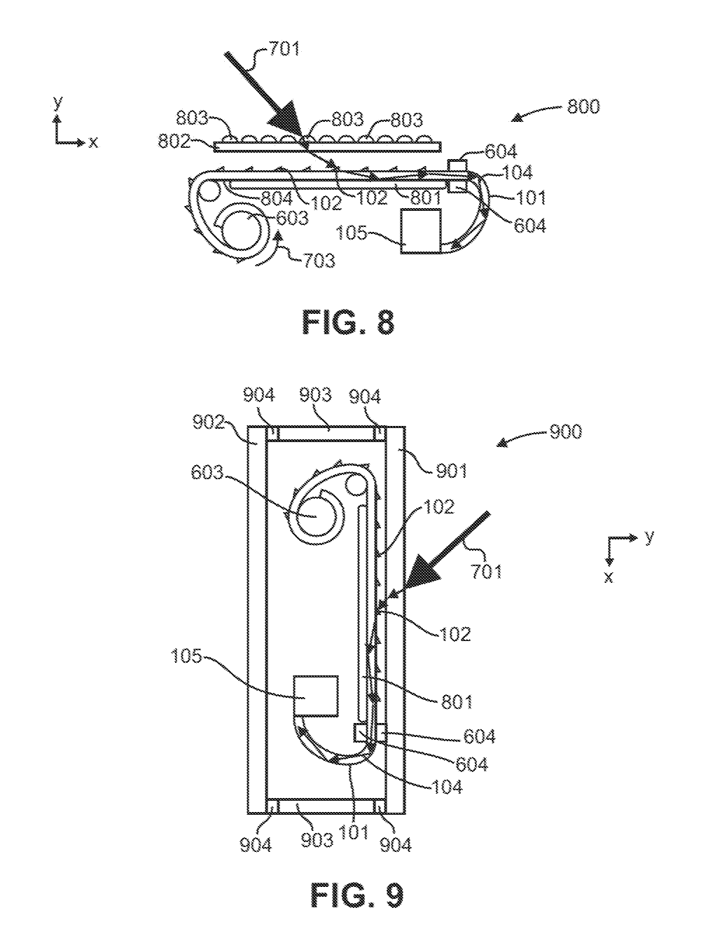

FIG. 8 is a cross-sectional side view of one embodiment of a solar energy system 800 including a stretchable lightguide film 101 with coupling features 102 positioned on the surface of the lightguide film 101. The lightguide film 101 is taut and supported by a lower support plate 801 beneath the lightguide film 101. An upper protective plate 802 including optical redirection features 803 on the upper surface is positioned above the lightguide film. Light 701 from the sun is redirected by the optical redirection features 803 in the upper protective plate 802 and is further redirected by the coupling features 102 into a lightguide condition where the light propagates in a direction represented by arrow 104 within the lightguide film 101 and into the out-coupling system 105. In this embodiment, the lightguide film 101 is held by clamps 604 near the out-coupling system 105. In this embodiment, the lower surface 804 of the lightguide film 101, the upper surface of the lower support plate 801, or both surfaces may include anti-blocking features to reduce the friction between the lower surface 804 of the lightguide film 101 and the upper surface of the lower support plate 801 such that the lightguide film 101 may be stretched uniformly using low stress by rotating the rod of the tension adjustment mechanism 603 in the direction shown by the arrow 703. lit one embodiment, the lightguide film 101 includes a lower cladding layer and the lower surface of the cladding layer of the lightguide film 101 includes a surface relief structure or microparticles embedded thereupon that cause surface relief that reduce the friction between the lightguide film 101 and the lower support plate 801. In one embodiment, the lower support plate 801 is also a lower reflective layer, such as a specularly reflecting aluminum plate, that reflects incident light that is not coupled into the lightguide film 101 such that upon reflection it may be coupled into the lightguide film 101.

FIG. 9 is a cross-sectional side view of one embodiment of an encapsulated solar energy system 900. In this embodiment, a stretchable lightguide film 101 includes coupling features 102 positioned on the surface of the lightguide film 101 and the lightguide film 101 is taut and held flat by a vertical support plate 801 adjacent the lightguide film 101. The lightguide film 101, vertical support plate 801, tension adjustment mechanism 603, and out-coupling system are encapsulated by a light transmitting front protective plate 901, a rear protective plate 902, and sidewalls 903 sealed together by a sealant 904. In this embodiment, the solar energy system 900 is a vertical solar energy system that can be mounted on the outer wall of a building. By encapsulating the solar energy system 900, the solar energy system 900 is protected from moisture and the environment. Light 701 from the sun passes through the light transmitting front protective plate 901 and is redirected by the coupling features 102 into a lightguide condition where the light propagates in a direction represented h arrow 104 within the lightguide film 101 and into the out-coupling system 105. In this embodiment, the lightguide film 101 is held by clamps 604 near the out-coupling system 105. Electrical wires or a thermal output such as pipes including fluid (not shown) may pass through the sealant 904 or a hole in one of the plates or sidewalls that is further sealed by a sealant. In one embodiment, the solar energy system 900 includes a front glass window and an aluminum housing that form the side and rear walls that protect the system when encapsulated using a sealant, such as an ethyl vinyl acetate sealant, for example. The housing, protective plates, supports, or sidewalls of the solar energy system 900 may be curved or non-planar in shape.

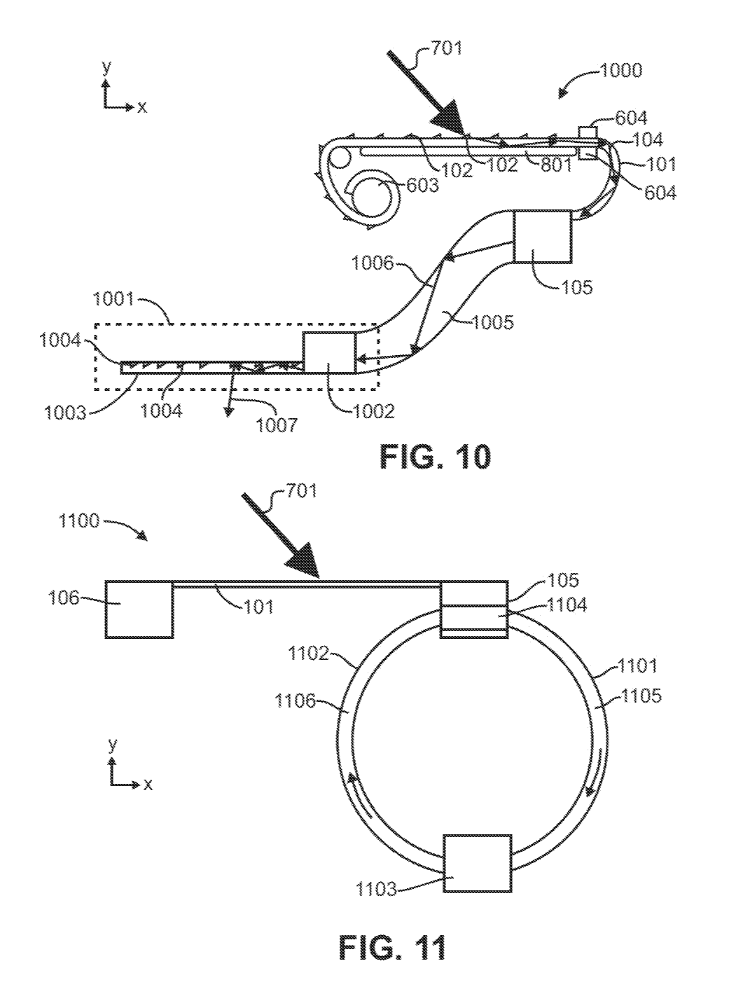

FIG. 10 is a cross-sectional side view of one embodiment of a solar energy system 1000 that provides daylighting illumination 1007. In this embodiment, a stretchable lightguide film 101 includes coupling features 102 positioned on the surface of the lightguide film 101 and the lightguide film 101 is supported by a lower support plate 801 below the lightguide film 101. Light 701 from the sun is redirected by the coupling features 102 into a lightguide condition where the light propagates in a direction represented by arrow 104 within the lightguide film 101 and into the out-coupling system 105. The light collector for the out-coupling system 105 is the input end of a fiber optic cable 1005 that collects the output from the bundled strips extending from the lightguide film 101 within the out-coupling system 105. Light 1006 from the out-coupling system 105 propagates through the fiber optic cable 1005 by total internal reflection to the daylighting light fixture 1001. The light 1006 passes through a light input coupler 1002 that includes an array of folded and bundled strips (not shown) extending from a lightguide film 1003. The light 1006 enters the strips in a waveguide condition, propagates through the folded strips to the body of the lightguide film 1003, propagates through the lightguide film 1003, and is redirected out of the lightguide film 1003 by light redirecting features 1004 to provide illumination 1007. In this embodiment, for example, the stretchable lightguide film 101 can be positioned on the roof of a building to receive solar radiation and direct the light by total internal reflection to a daylighting light fixture 1001 positioned within the building to illuminate an interior region of the building. When the position of the sun changes, the lightguide film 101 can be stretched for contracted) by the tension adjustment mechanism 603 such that the coupling features 102 continue to redirect light 701 into the lightguide film 101 such that light 1006 propagates to the daylighting light fixture 1001 and provides illumination 1007.

FIG. 11 is a cross-sectional side view of one embodiment of a solar energy system 1100 that provides solar thermal energy. In this embodiment, a lightguide film 101 is stretched or contracted by a tension adjustment mechanism 106 to track the solar light radiation 701 incident on the lightguide film 101 such that the tot 701 continues to be coupled into the lightguide film 101 and propagate to the out-coupling system 105. In this embodiment, the out-coupling system 105 includes a light absorbing element 1104 that absorbs the light exiting the strips from the lightguide film 101 and transfers the thermal energy to a thermal transfer fluid 1105. The heated thermal transfer fluid 1105 travels through a supply pipe 1101 to a heat exchanger 1103. The heat exchanger transfers heat into a specific environment. For example, in one embodiment, the heat exchanger is within a hot water tank such that the solar energy system 1100 heats water for a building. In another embodiment, the heat exchanger 1103 transfers heat to a ventilation system to provide heating for a building. After the heat is transferred out of the heat exchanger 1103 into the environment. the cooler fluid 1106 circulates back to light absorbing element through the return pipe 1102 to be re-heated. In one embodiment, a solar energy system for collecting light includes a first stretchable lightguide film configured to optically couple light into a lightguide condition in the first stretchable lightguide film. A first set of output coupling strips. extend from the first stretchable lightguide film. Each output coupling strip of the first set of output coupling strips has an end, and the first set of output coupling strips are bundled at the ends. The light coupled into the lightguide condition in the first stretchable lightguide film propagates to the ends of the first set of output coupling strips and into a first light collector. In a particular embodiment, a second stretchable lightguide film is positioned beneath the first stretchable lightguide film. The second stretchable lightguide film includes a second set of output coupling strips extending from the second stretchable lightguide film.

Each output coupling strip of the second set of output coupling strips has an end, and the second set of output coupling strips are bundled at the ends. Light passing through the first stretchable lightguide film without coupling into the lightguide condition within the first stretchable lightguide film is coupled into a lightguide condition in the second stretchable lightguide film and propagates to the ends of the second set of output coupling strips and into a second light collector. When light incident upon the first stretchable lightguide film from a first angle is not totally internally reflected within the first stretchable lightguide film, the first stretchable lightguide film is stretchable to redirect light incident upon the first stretchable lightguide film from the first angle to a second angle that totally internally reflects in a lightguide condition within the first stretchable lightguide film. In a further embodiment, the first stretchable lightguide film includes a coupling feature region defined by one or more coupling features that change in at least one of a size, a shape, and a relative position when the first stretchable lightguide film is stretched such that the one or more coupling features redirect the light from the first angle to the second angle. The coupling feature region has a first portion and a second portion with the first portion bent underneath the second portion when the first stretchable lightguide film is stretched. A tension adjustment mechanism configured to change a stress applied to the first stretchable lightguide film to change a length of the first stretchable lightguide film in a first stretch direction. A support plate is positioned beneath the first stretchable lightguide film, and is configured to reduce the sag of the first stretchable lightguide film. In one embodiment, the first stretchable lightguide film is encapsulated in the solar energy system and protected from moisture. The solar energy system may also include a feedback mechanism configured to provide information for adjusting the stress applied to the first stretchable lightguide film by the tension adjustment mechanism to facilitate increasing the film coupling efficiency. In certain embodiments, the feedback mechanism includes one or more of the following: a tension mechanism, a positional mechanism, and an optical feedback mechanism.

In one embodiment, the first light collector includes a photovoltaic cell and the solar energy system is a photovoltaic system that collects solar radiation and converts the solar radiation to electrical energy. In an alternative embodiment, the first light collector includes a heat absorber and the solar energy system is a solar thermal system that transfers thermal energy. In another embodiment, the first light collector includes a light emitting fixture that outputs the light from the first set of output coupling strips in the form of illumination and the solar energy system is a daylighting system.

In one embodiment, a solar energy system includes a stretchable lightguide One or more coupling features are positioned on or within the stretchable lightguide film. The one or more coupling features are configured to redirect light incident from a first angular range into a total internal reflection condition within the stretchable lightguide film. A tension adjustment mechanism is configured to stretch and contract the stretchable lightguide film such that the one or more coupling features redirect light incident from a second angular range into a total internal reflection condition within the stretchable lightguide film. In one embodiment, at least one of a size, a shape and a relative position of the one or more coupling features changes when the tension adjustment mechanism stretches or contracts the stretchable lightguide film. A plurality of strips extend from the stretchable lightguide film. Each strip of the plurality of strips has an end, and the plurality of strips are bundled at the ends and optically coupled to a light collector. Light propagating in a lightguide condition within the stretchable lightguide film propagates through the plurality of strips to the light collector. The solar energy system is configured to track the sun travelling across the sky from a first position emitting light incident upon the stretchable lightguide film in the first angular range to a second position emitting light incident upon the stretchable lightguide film in the second angular range to facilitate providing light to the light collector.

In one embodiment, as method for collecting light includes increasing or decreasing at least one dimension of a lightguide film including one or more coupling features to optically couple light into the lightguide film. In one embodiment, increasing or decreasing at least one dimension of a lightguide film includes changing an acceptance angle of the lightguide film for coupling light into the lightguide film in a total internal reflection condition within the lightguide film. The lightguide film is stretched or contracted to couple light from the sun into the lightguide film as the sun traverses the sky.

The described system and methods are not limited to the specific embodiments described herein, in addition, components of the system and steps of the methods may be practiced independent and separate from other components and method steps described herein. Each component and each method step also can be used in combination with other systems and methods.

Having described aspects of the disclosure in detail, it will be apparent that modifications and variations are possible without departing from the scope of aspects of the disclosure as defined in the appended claims. As various changes could he made in the above constructions, products, and methods without departing from the scope of aspects of the disclosure, it is intended that all matter contained in the above description and shown in the accompanying drawings shall be interpreted as illustrative and not in a limiting sense.

What is claimed is:

1. A solar energy system for collecting light, said solar energy system comprising a first stretchable lightguide film configured to optically couple light into a lightguide condition in the first stretchable lightguide film.

2. The solar energy system of claim 1 further comprising a first set of output coupling strips extending from the first stretchable lightguide film, each output coupling strip of the first set of output coupling strips having an end, the first set of output coupling strips bundled at the ends, wherein the light coupled into the lightguide condition in the first stretchable lightguide film propagates to the ends of the first set of output coupling strips and into a first light collector.

3. The solar energy system of claim 2 further comprising a second stretchable lightguide film positioned beneath the first stretchable lightguide film, the second stretchable lightguide film comprising a second set of output coupling strips extending from the second stretchable lightguide film, each output coupling strip of the second set of output coupling strips having an end, the second set of output coupling strips bundled at the ends, wherein light passing through the first stretchable lightguide film without coupling into the lightguide condition within the first stretchable lightguide film is coupled into a lightguide condition in the second stretchable lightguide film and propagates to the ends of the second set of output coupling strips and into a second light collector.

4. The solar energy system of claim 1 wherein light incident, upon the first stretchable lightguide film from a first angle is not totally internally reflected within the first stretchable lightguide film, and wherein the first stretchable lightguide film is stretchable to redirect light incident upon the first stretchable lightguide film from the first angle to a. second angle that totally internally reflects in a lightguide condition within the first stretchable lightguide film.

5. The solar energy system of claim 4 wherein the first stretchable lightguide film further comprises a coupling feature region defined by one or more coupling features that change in at least one of a size, a shape, and a relative position when the first stretchable lightguide film is stretched such that the one or more coupling features redirect the light from the first angle to the second angle.

6. The solar energy system of claim 5 wherein the coupling feature region has a first portion and a second portion, the first portion bent underneath the second portion when the first stretchable lightguide film is stretched.

7. The solar energy system of claim 4 further comprising a tension adjustment mechanism configured to change a stress applied to the first stretchable lightguide film to change a length of the first stretchable lightguide film in a first stretch direction.

8. The solar energy system of claim 7 further comprising, a support plate positioned beneath the first stretchable lightguide film, the support plate configured to reduce the sag of tire first stretchable lightguide film.

9. The solar energy system of claim 7 wherein the first stretchable lightguide him is encapsulated in the solar energy system and protected from moisture.

10. The solar energy system of claim 7 further comprising a feedback mechanism configured to provide information for adjusting the stress applied to the first stretchable lightguide film by the tension adjustment mechanism to facilitate increasing the film coupling efficiency.

11. The solar energy system of claim 10 wherein the feedback mechanism comprises one or more of the following: a tension mechanism, a positional mechanism, and an optical feedback mechanism.

12. The solar energy system of claim 2 wherein the first light collector comprises a photovoltaic cell and the solar energy system is a photovoltaic system that collects solar radiation and converts the solar radiation to electrical energy.

13. The solar energy system of claim 2 wherein the first light collector comprises a heat absorber and the solar energy system is a solar thermal system that transfers thermal energy.

14. The solar energy system of claim 2 wherein the first light collector comprises a light emitting fixture that outputs the light from the first set of output coupling, strips in the form of illumination and the solar energy system is a daylighting system.

15. A solar energy system comprising:
a stretchable lightguide film;
one or more coupling features positioned on or within the stretchable lightguide film, the one or more coupling features configured to redirect light incident from a first angular range into a total internal reflection condition within the stretchable lightguide film; and
a tension adjustment mechanism configured to stretch and contract the stretchable lightguide film such that the one or more coupling features redirect light incident from a second angular range into a total internal reflection condition within the stretchable lightguide film.

16. The solar energy system of claim 15 wherein at least one of a size, a shape and a relative position of the one or more coupling features changes when the tension adjustment mechanism stretches or contracts the stretchable lightguide

17. The solar energy system of claim 15 further comprising a plurality of strips extending from the stretchable lightguide film, each strip of the plurality of strips having an end, the plurality of strips bundled at the ends and optically coupled to a light collector, wherein light propagating in a lightguide condition within the stretchable lightguide film propagates through the plurality of strips to the light collector.

18. The solar energy system of claim 17 wherein the solar energy system is configured to track the sun travelling across the sky from a first position emitting light incident upon the stretchable lightguide film in the first angular range to a second position emitting light incident upon the stretchable lightguide film in the second angular range to facilitate providing light to the light collector.

19. A method for collecting light, said method comprising increasing or decreasing at least one dimension of a lightguide film including one or more coupling features to optically couple light into the lightguide film.

20. The method of claim 19 wherein increasing or decreasing at least one dimension of a lightguide film changes an acceptance angle of the lightguide film for coupling light into the lightguide film in a total internal reflection condition within the lightguide film.

21. The method of claim 19 wherein the lightguide film is stretched or contracted to couple light from the sun into the lightguide film as the sun traverses the sky.
